(19) United States
(12) Patent Application Publication
(10) Pub. No.: US 2025/0012868 A1
(43) Pub. Date: Jan. 9, 2025

(54) METHOD FOR STANDARDIZING DECOMMISSIONING DEFINITION OF POWER BATTERIES AND SYSTEM THEREOF

(71) Applicant: SHANDONG UNIVERSITY, Jinan (CN)

(72) Inventors: Chenghui ZHANG, Jinan (CN); Yunlong SHANG, Jinan (CN); Teng WANG, Jinan (CN); Yuhao ZHU, Jinan (CN)

(73) Assignee: SHANDONG UNIVERSITY, Jinan (CN)

(21) Appl. No.: 18/763,074

(22) Filed: Jul. 3, 2024

(30) Foreign Application Priority Data
Jul. 4, 2023 (CN) 2023108132436

(51) Int. Cl. G01R 31/392; G01R 31/387; H01M 10/54; H02J 7/00

(52) U.S. Cl. CPC G01R 31/392; G01R 31/387; H02J 7/005; H01M 10/54

(57) ABSTRACT

A method for standardizing a decommissioning definition of power batteries, including: obtaining power battery capacity data and SOH data; obtaining capacity degradation gradient by subtracting battery capacity of current charge-discharge cycle by battery capacity of previous charge-discharge cycle, and obtaining index of decommissioning (IoD) of power battery by dividing capacity degradation gradient by a square of SOH of current charge-discharge cycle; and when IoD is less than a set threshold, dismantling, disassembling and separating the power battery; otherwise, continuing to use the power battery. An aging state of battery is evaluated comprehensively based on two indexes—the SOH and the capacity degradation gradient, so that a new IoD of the battery is proposed. Each cell can be comprehensively evaluated according to various real-time states of battery, thereby achieving individual decommissioning, which ensures safe use of battery and increases the utilization rate of battery.

### TECHNICAL FIELD

The present disclosure relates to the technical field of evaluation of power battery decommissioning, and in particular, to a method for standardizing a decommissioning definition of power batteries and a system thereof.

### BACKGROUND

The statements in this section only provide the background related to the present disclosure and do not necessarily constitute the prior art.

Lithium ion batteries have been widely used in energy supply systems of electric vehicles due to their advantages of high energy density, long cycle life, stable usability, and the like. However, during charge-discharge cycles of the lithium ion batteries, the energy storage capacity and state of health (SOH) of the batteries will decrease as the number of cycles increases. When the energy storage capacity and SOH of the batteries decrease to an extent, there may be phenomena such as “sharp drop” in the battery capacity, leakage of electrolyte, and swollen batteries. If these batteries are continued to be used, many safety hazards may be caused. However, the same type of cells may exhibit different degradation characteristics due to different use conditions. Therefore, proper decommissioning of batteries cannot only ensure safe use of the batteries, but also achieve maximum utilization of the batteries.

An aging mechanism of the lithium ion battery is complex, and the degradation in capacity is nonlinear and uncertain, making it difficult to establish an accurate aging model. A battery typically exhibits different degradation characteristics in different capacity degradation stages, generally including two stages: In the first stage, the capacity degradation gradient changes little, and the SOH slowly drops. In the second stage, the capacity degradation gradient gradually increases, and the drop rate of the SOH gradually increases too. The different degradation characteristics of the two stages cause the changes in the overall capacity degradation gradient and SOH of the battery to be nonlinear, and there are also differences between different cells. The traditional decommissioning standard for power batteries is 80% SOH. This “one size fits all” method cannot achieve proper decommissioning according to the degradation characteristics of cells, so that the batteries cannot be fully used, and the safety of use cannot be ensured. There is boundedness. Under actual working conditions, batteries exhibit different degradation characteristics due to different external use conditions and differences internal chemical reaction environments. Cells should be reasonably decommissioned according to their own degradation characteristics: If a battery has a large SOH and a large capacity degradation gradient, the battery cannot ensure the safety of use according to the decommissioning standard of 80% SOH, so that the battery can be considered to be decommissioned early. If a battery has a small SOH and its capacity degradation gradient changes little, the battery cannot be fully used according to the decommissioning standard of 80% SOH, so that the battery can be considered to be continued to be used, and the decommissioning time defers. Therefore, how to accurately recognize a decommissioning point of a battery and evaluate an aging state of a battery in real time and accurately based on new indicators has become a hot research topic in the field of power battery health management.

Many scholars have conducted extensive research on the recognition of decommissioning points of batteries, but currently there is still a lack of comprehensive evaluation indicators for accurate and proper decommissioning of lithium ion batteries. Chinese invention patent CN115166563A provides a method for evaluating states of power batteries and screening a decommissioned battery. The batteries are initially screened according to voltage data and are tested using a standard capacity to obtain data such as a battery capacity and resistance. The specific method achieves high-precision and high-reliability data acquisition by charge-discharge the batteries. Based on the battery capacity-voltage curve derivation and quadratic derivation, a first indicator and a second indicator of set peaks of a derived curve are respectively extracted, so as to separately determine battery types and consistency and achieve secondary screening. Third-level screening is performed based on battery direct current (DC) internal resistance and the quadratic screening. However, this is a time-consuming and energy-wasting process, which will make decommissioning of a large scale of batteries difficult. In Chinese invention patent CN109596983B, a slope turning point according to a relationship curve between an open circuit voltage (OCV) and discharge capacity of a battery. By comparing a voltage corresponding to the slope turning point in a charge-discharge process with a cut-off voltage, it is determined whether the battery is decommissioned later. However, the battery needs to stand still for long time to obtain the OCV, which has poor economy and low efficiency. Chinese invention patent CN116125301A provides a method for evaluating a reliability state of a lithium battery. Reliability parameters of various parameters of a current battery in a threshold range are calculated separately according to upper and lower threshold intervals of a plurality of parameters of safe running of the battery, thereby evaluating the reliability state of the battery and determining whether the battery is decommissioned. However, this method depends on empirically provided parameters, so it is subjective.

In summary, the traditional decommissioning point of a battery is based on 80% SOH, and there is currently a lack of standardization methods to accurately recognize a decommissioning point of a battery. Most methods are based on a single feature or have subjectivity, so these methods have boundedness.

### SUMMARY

To solve the shortcomings in the prior art, the present disclosure provides a method for standardizing a decommissioning definition of power batteries and a system thereof. An aging state of a battery is evaluated comprehensively based on two indicators, namely, an SOH and a capacity degradation gradient, so that a new index of decommissioning of the battery is proposed. Each cell can be comprehensively evaluated according to various real-time states of a battery, thereby achieving individual decommissioning. This ensures safe use of a battery and increases the utilization rate of a battery.

To achieve the above objectives, the present disclosure uses the following technical solutions:

A first aspect of the present disclosure provides a method for standardizing a decommissioning definition of power batteries.

The method for standardizing the decommissioning definition of the power batteries includes the following processes:
obtaining capacity data and SOH data of a power battery;
obtaining a capacity degradation gradient by subtracting a capacity of the battery in a current charge-discharge cycle by a capacity of the battery in a previous charge-discharge cycle, and then obtaining an index of decommissioning of the power battery by dividing the capacity degradation gradient by a square of a value of SOH of the current charge-discharge cycle; and
when the index of decommissioning is less than a set threshold, dismantling, disassembling and separating the power battery to realize the decommissioning; otherwise, continuing to use the power battery.

As a further limitation on the first aspect of the present disclosure, obtaining of a set threshold includes:
obtaining a curve of indexes of decommissioning of a plurality of power batteries of the same type with respect to a number of cycles; and
obtaining a distribution of the indexes of decommissioning in the value X % of SOH according to the curve, and obtaining the set threshold according to the distribution of the indexes of decommissioning.

As a further limitation on the first aspect of the present disclosure, the value X % of SOH is 80% SOH.

As a further limitation on the first aspect of the present disclosure, the distribution of the indexes of decommissioning conforms to gamma distribution, and an extreme point of the gamma distribution represents a maximum distribution frequency of the indexes of decommissioning at the value; and a ratio of a shape parameter of the gamma distribution to an inverse scale parameter is the set threshold.

A second aspect of the present disclosure provides a system for standardizing a decommissioning definition of power batteries.

The system for standardizing the decommissioning definition of the power batteries includes:
a data obtaining module, configured to obtain capacity data and SOH data of a power battery; and
an index of decommissioning calculation module, configured to: obtain a capacity degradation gradient by subtracting a capacity of the battery in a current charge-discharge cycle by a capacity of the battery in a previous charge-discharge cycle, and then to obtain an index of decommissioning of the power battery by dividing the capacity degradation gradient by a square of a value of SOH of the current charge-discharge cycle; and
when the index of decommissioning is less than a set threshold, dismantling, disassembling and separating the power battery to realize the decommissioning; otherwise, continuing to use the power battery.

As a further limitation on the second aspect of the present disclosure, obtaining of a set threshold includes:
obtaining a curve of indexes of decommissioning of a plurality of power batteries of the same type with respect to a number of cycles; and
obtaining a distribution of the indexes of decommissioning in the value X % of SOH according to the curve, and obtaining the set threshold according to the distribution of the indexes of decommissioning.

As a further limitation on the second aspect of the present disclosure, the value X % of SOH is 80% SOH.

As a further limitation on the second aspect of the present disclosure, the distribution of the indexes of decommissioning conforms to gamma distribution, and an extreme point of the gamma distribution represents a maximum distribution frequency of the indexes of decommissioning at the value; and a ratio of a shape parameter of the gamma distribution to an inverse scale parameter is the set threshold.

A third aspect of the present disclosure provides a non-transitory computer-readable storage medium, having a program stored thereon, wherein the program, when run by a processor, implements the steps in the method for standardizing the decommissioning definition of the power batteries as described in the first aspect of the present disclosure.

A fourth aspect of the present disclosure provides an electronic device, including a memory, a processor, and a program stored on the memory and runnable on the processor, wherein the processor, when running the program, implements the steps in the method for standardizing the decommissioning definition of the power batteries as described in the first aspect of the present disclosure.

Compared with the prior art, the present disclosure has the beneficial effects below:

1. The present disclosure comprehensively evaluates an aging state of a battery based on two indexes, namely, the SOH and the capacity degradation gradient, so that a new index of decommissioning of the battery is proposed. This index can comprehensively evaluate each cell according to various real-time states of a battery, thereby achieving individual decommissioning. This ensures safe use of a battery and increases the utilization rate of a battery.

2. The present disclosure avoids the traditional “one size fits all” decommissioning determination method which takes 80% SOH as the life of a battery, can reasonably and accurately decommission a cell according to a degradation characteristic of the cell, and can calculate an index of decommissioning of a power battery in real time. The calculation method is simple, has high robustness, and provides an important reference for the surplus value evaluation and cascade utilization of battery decommissioning.

The advantages of additional aspects of the present disclosure will be partially provided in the following descriptions, some of which will become apparent from the following descriptions, or learned through the practice of the present disclosure.

### BRIEF DESCRIPTION OF THE DRAWINGS

The accompanying drawings of this specification that constitute a portion of the present disclosure are used to provide a further understanding of the present disclosure and form a part of the present application. The illustrative embodiments and their explanations of the present disclosure are used to explain the present disclosure and do not constitute an improper limitation on the present disclosure.

FIG. 1 is a flowchart of standardized recognition of a decommissioning point of a lithium ion battery provided according to Embodiment 1 of the present disclosure;

FIG. 2 is a schematic diagram of capacity degradation curves of 124 lithium iron phosphate (LFP) batteries provided according to Embodiment 1 of the present disclosure;

FIG. 3 is a schematic diagram of curves where indexes of decommissioning (IoDs) of 124 batteries change with a number of cycles provided according to Embodiment 1 of the present disclosure;

FIG. 4 is a schematic diagram of distribution of IoDs of 124 batteries with 80% SOH provided according to Embodiment 1 of the present disclosure;

FIG. 5 is a schematic diagram of a curve of degradation of a battery with BDC=1 and a standard decommissioning point provided according to Embodiment 1 of the present disclosure; and

FIG. 6 is a schematic diagram of life prolonging or shortening ratio of a battery provided according to Embodiment 1 of the present disclosure.

### DETAILED DESCRIPTION

The present disclosure will be further explained below in conjunction with the accompanying drawings and embodiments.

It should be pointed out that the following detailed explanations are exemplary and aim to provide a further explanation of the present disclosure. Unless otherwise defined, all technical and scientific terms used herein have the same meaning as commonly understood by a person of ordinary skill in the art to which the present disclosure belongs.

It should be noted that the terms used here are only for describing specific implementations and are not intended to limit the exemplary implementations according to the present disclosure. As used here, unless otherwise explicitly stated in the context, a singular form is also intended to include a plural form. In addition, it should also be understood that when the terms “include” and/or “comprise” are used in this specification, they indicate the existence of features, steps, operations, devices, assemblies, and/or combinations thereof.

The embodiments of the present disclosure and features in the embodiments may be mutually combined without conflicts.

### Embodiment 1

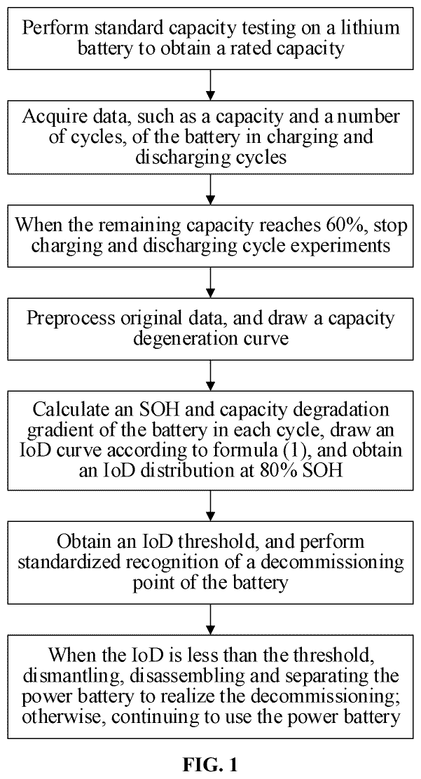

As shown in FIG. 1, Embodiment 1 of the present disclosure provides a method for standardizing a decommissioning definition of a power battery, to standardize recognition of a decommissioning point of the power battery, so as to achieve an efficient use of the power battery, including the steps as follows: comprehensively evaluating a degradation state of the battery according to two indexes: a capacity degradation gradient of the battery and a SOH of the battery, and determining whether the battery is decommissioned: subtracting, according to a capacity degradation curve of the battery, a capacity of a current charge-discharge cycle by a capacity of a previous charge-discharge cycle to obtain a degradation gradient ∇Cᵢ, and dividing a capacity degradation gradient VC, by the square of SOH, of the current charge-discharge cycle to obtain a new evaluation index, namely, an index of decommissioning (IoD) of the battery; searching for an appropriate IoD threshold IoDₜₕᵣ of the battery; and performing standardized definition of an end of the life, i.e. a decommissioning point, of the battery according to IoDₜₕᵣ. A specific calculation formula is as shown in formula (1).

$$IoD = \frac{{SOH}_{i}^{2}}{∇ C} \qquad ( 1 )$$

Wherein ∇C at the denominator position represents a degradation magnitude of a discharging capacity of the battery after each cycle; as the number of cycles increases, ∇C will become larger and larger; and a value of SOH at the numerator position will become smaller and smaller with the number of cycles, but will be the square of the value of SOH to keep a change rate at the same order of magnitude as ∇C. In summary, IoD will gradually decrease as the number of cycles increases, and the aging state of the battery can be reflected in multiple angles.

Specific steps are as follows:
(1) performing standard capacity testing for three times on a lithium ion battery, and using a mean value of the three tested capacities as a rated capacity of the battery;
(2) performing cyclic charge-discharge experiments on the battery to obtain data of the battery, such as a capacity, a current, a voltage, and a temperature, corresponding to each charge-discharge cycle, and preprocessing the acquired data;
(3) when an available capacity of the battery is less than 60% of the rated capacity, stopping the cyclic charge-discharge experiment, and recording the number of cycles at this time;
(4) denoising original data, drawing a curve where the capacity degradation changes with the number of cycles, and then performing curve smoothing processing;
(5) calculating an SOH and capacity degradation gradient corresponding to each cycle according to the capacity degradation curve, and further obtaining an IoD curve; and
(6) obtaining an IoD distribution at 80% SOH according to the IoD curve to further obtain threshold IoDₜₕᵣ, and performing standardized recognition of a decommissioning point of the battery through a relationship between IoDₜₕᵣ and the capacity.

In the present embodiment, 80% SOH is preferred. It is defined according to the current general standard, including a situation where a set ratio changes after further development of a battery technology in the future. For example, there may be a situation less than 80% (e.g. 75% or 60%). Only 80% is taken as an example here. Repetitions will be omitted here.

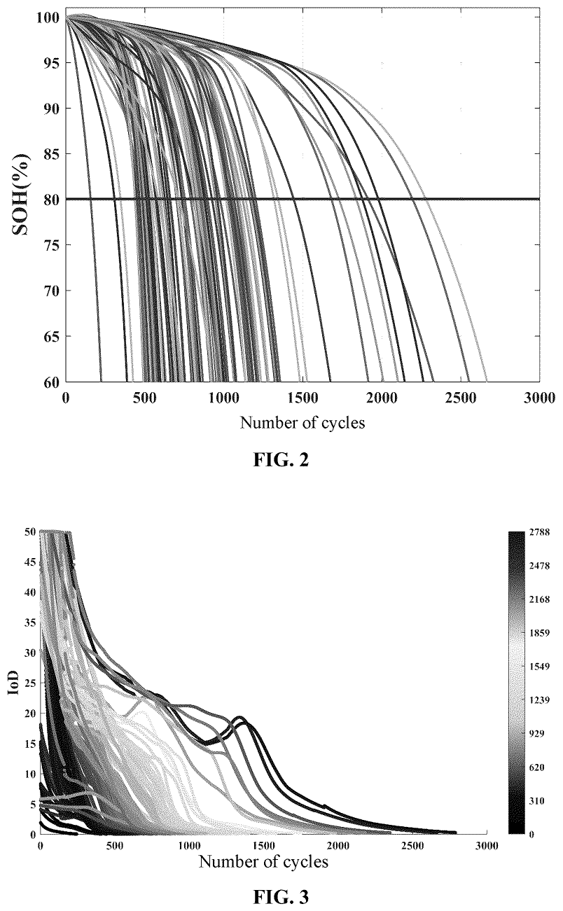

The present disclosure verifies the feasibility and effectiveness of the provided method using an existing publicly experimental data set. A lithium iron phosphate (LFP) battery with a rated capacity of 1.1 Ah and a nominal voltage of 3.3 V is cyclically charged and discharged in a forced convection temperature control box at 30° C. The data set contains a total of 124 batteries. The curves of which the SOHs of all the batteries change with the number of charge-discharge cycles are as shown in FIG. 2. The transverse line in FIG. 2 represents 80% SOH. In the traditional method, this line is used as a battery decommissioning standard. As shown in FIG. 2, in the traditional method, only the SOH is considered, but a combined impact of the SOH and the capacity degradation gradient is not considered. When a battery has a high SOH and a large capacity degradation gradient, if the battery is decommissioned at 80% SOH, it is hard to ensure the safety of the battery. When a battery has a low SOH and a small capacity degradation gradient, if the battery is decommissioned at 80% SOH, the battery cannot be fully used.

To solve this problem, a battery decommissioning coefficient is calculated according to formula (1). To avoid the IoD approaching infinity, the single capacity degradation gradient is limited to 0.02 Ah/time, as shown in FIG. 3. According to FIG. 3, it can be seen that the IoD of a cell gradually decreases and changes a lot in the early stage of degradation, and the range and rate of change gradually decrease in the late stage of degradation. Analysis of an overall battery pack shows that a shorter life of a battery indicates a smaller range of change of the IoD and a larger rate of approaching to 0; and a longer life of a battery indicates a larger range of change of the IoD and a smaller rate of approaching to 0. To some extent, this reflects the degradation characteristics of the battery pack and an aging state of a cell. An IoD distribution of the battery pack at 80% SOH is further obtained, as shown in FIG. 4.

According to analysis in FIG. 4, it can be seen that the IoD at 80% SOH conforms to Gamma distribution, as shown in formula (2).

$$f ( x , β , α ) = \frac{{β}^{α}}{Γ ( α )} {x}^{α - 1} {e}^{- β x} , \qquad ( 2 )$$

$$x > 0$$

Where α is a shape parameter, and β is an inverse scale parameter, which can be calculated to α=8.56, β=8.33. An extreme point that conforms to the Gamma distribution represents a maximum distribution frequency of the IoD at this value and some batteries are decommissioned here.

$${IoD}_{thr} = \frac{α}{β} \approx 1$$

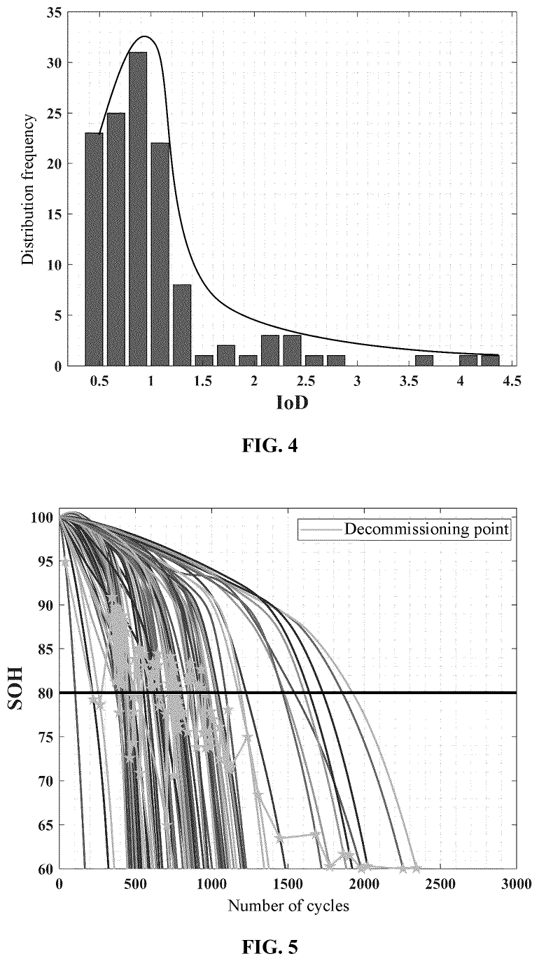

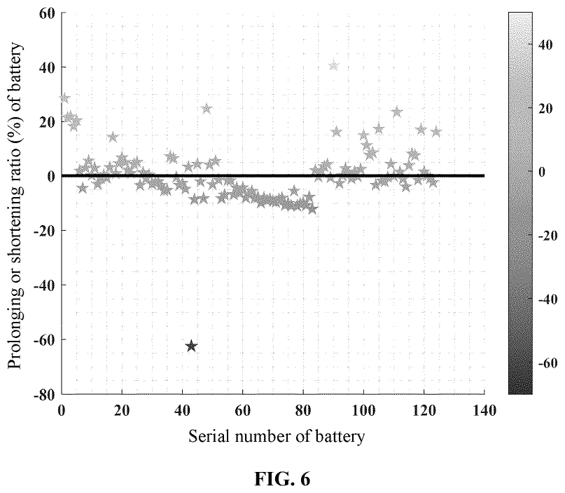

can be obtained after calculation. IoD=1 is used as a battery decommissioning standard. If the IoD value of the battery is less than 1 at this time, the battery can be considered for decommissioning. If the IoD value of the battery is still greater than 1, the battery can be continued to be used. Based on this, a battery capacity degradation curve is drawn, and the decommissioning point of the battery is calibrated, as shown in FIG. 5. FIG. 6 shows life prolonging or shortening ratios of 124 batteries in the standard decommissioning method.

According to FIG. 5 and FIG. 6, analysis can show that the degradations of most batteries are inconsistent. IoD=1 is used as a battery decommissioning threshold. The threshold is used as the battery decommissioning standard. The marked points in FIG. 5 represent the standardized decommissioning points of the battery, and the black transverse line represents the decommissioning point of the battery defined by 80% SOH. FIG. 6 shows distribution of a prolonging or shortening ratio of a decommissioning life of a battery compared to traditional 80% SOH in the method of the present disclosure. It can be seen that the lives of very few batteries have been shortened by about 60% and prolonged by about 40%, and the lives of most batteries have been shortened by −10% and prolonged by 20%.

The present disclosure no longer uses SOH=80% as the decommissioning point, but comprehensively evaluates the decommissioning point of the battery according to the SOH and capacity degradation gradient of the battery. For a battery with high degradation speed and amplitude, even if the SOH is high, the battery should be decommissioned in advance and replaced with a new power battery in a timely manner to ensure the safety of use of batteries. For a battery with low degradation speed and a large number of cycles, the later degradation is approximately linear. Even if the SOH is low, the degradation speed is low, so that the battery will not be decommissioned until it is used for a period of time, so as to increase the capacity utilization rate of batteries. Therefore, the standardized end of life recognition method provided by the present disclosure breaks through the bottleneck of the traditional method using SOH-80% as the end of life and can make more proper use of batteries, ensuring the safety of batteries.

And, the power batteries that meet the decommissioning standards, after dismantling, disassembly, separating and other processes, some can still be used in application scenarios with low performance requirements after re-assembly, thus realizing “hierarchical utilization”. For the parts of the batteries that cannot be used for the “hierarchical utilization”, they are broken, and lithium, cobalt, nickel and other raw materials in the battery are extracted, and recycled into new batteries.

### Embodiment 2

Embodiment 2 of the present disclosure provides a system for standardizing a decommissioning definition of power batteries, including:
a data obtaining module, configured to obtain capacity data and SOH data of a power battery; and
an index of decommissioning calculation module, configured to: subtract a capacity of the battery in a current charge-discharge cycle by a capacity of the battery in a previous charge-discharge cycle to obtain a degradation gradient, and divide a capacity degradation gradient by a square of a value of SOH of the current charge-discharge cycle to obtain an index of decommissioning of the power battery; and
when the index of decommissioning is less than a set threshold, dismantling, disassembling and separating the power battery to realize the decommissioning; otherwise, continue to use the power battery.

Working methods of all the modules of the system are the same as those in the method for standardizing the decommissioning definition of the power batteries provided in Embodiment 1. Repetitions will be omitted here.

### Embodiment 3

Embodiment 3 of the present disclosure provides a non-transitory computer-readable storage medium, having a program stored thereon, wherein the program, when run by a processor, implements the steps in the method for standardizing the decommissioning definition of the power batteries as described in Embodiment 1.

### Embodiment 4

Embodiment 4 of the present disclosure provides an electronic device, including a memory, a processor, and a program stored on the memory and runnable on the processor, wherein the processor, when running the program, implements the steps in the method for standardizing the decommissioning definition of the power batteries as described in Embodiment 1.

The above descriptions are only preferred embodiments of the present disclosure, and are not intended to limit the present disclosure. For those skilled in the art, the present disclosure may have various modifications and changes. Any modification, equivalent replacement, and improvement made within the spirit and scope of the present disclosure shall fall within the protection scope of the present disclosure.

1. A method for standardizing a decommissioning definition of power batteries, comprising the following processes:
obtaining capacity data and state of health (SOH) data of a power battery;
obtaining a capacity degradation gradient by subtracting a capacity of the battery in a current charge-discharge cycle by a capacity of the battery in a previous charge-discharge cycle, and then obtaining an index of decommissioning of the power battery by dividing the capacity degradation gradient by a square of a value of SOH of the current charge-discharge cycle; and
when the index of decommissioning (IoD) is less than a set threshold, dismantling, disassembling and separating the power battery to realize the decommissioning; otherwise, continuing to use the power battery.

2. The method for standardizing the decommissioning definition of the power batteries according to claim 1, wherein
obtaining of a set threshold comprises:
obtaining a curve of indexes of decommissioning of a plurality of power batteries of the same type with respect to a number of cycles; and
obtaining a distribution of the indexes of decommissioning in the value of SOH being X % according to the curve, and obtaining the set threshold according to the distribution of the indexes of decommissioning.

3. The method for standardizing the decommissioning definition of the power batteries according to claim 2, wherein
the value X % of SOH is 80% SOH.

4. The method for standardizing the decommissioning definition of the power batteries according to claim 2, wherein
the distribution of the indexes of decommissioning conforms to gamma distribution, and an extreme point of the gamma distribution represents a maximum distribution frequency of the indexes of decommissioning at the value; and a ratio of a shape parameter of the gamma distribution to an inverse scale parameter is the set threshold.

5. A system for standardizing a decommissioning definition of power batteries, comprising:
a data obtaining module, configured to obtain capacity data and SOH data of a power battery; and
an index of decommissioning calculation module, configured to: obtain a capacity degradation gradient by subtracting a capacity of the battery in a current charge-discharge cycle by a capacity of the battery in a previous charge-discharge cycle, and then obtaining an index of decommissioning of the power battery by dividing the capacity degradation gradient by a square of a value of SOH of the current charge-discharge cycle; and
when the index of decommissioning is less than a set threshold, dismantling, disassembling and separating the power battery to realize the decommissioning; otherwise, continue to use the power battery.

6. The system for standardizing the decommissioning definition of the power batteries according to claim 5, wherein
obtaining of a set threshold comprises:
obtaining a curve of indexes of decommissioning of a plurality of power batteries of the same type with respect to a number of cycles; and
obtaining a distribution of the indexes of decommissioning in the value of SOH being X % according to the curve, and obtaining the set threshold according to the distribution of the indexes of decommissioning.

7. The system for standardizing the decommissioning definition of the power batteries according to claim 6, wherein
the value X % of SOH is 80% SOH.

8. The system for standardizing the decommissioning definition of the power batteries according to claim 6, wherein
the distribution of the indexes of decommissioning conforms to gamma distribution, and an extreme point of the gamma distribution represents a maximum distribution frequency of the indexes of decommissioning at the value; and a ratio of a shape parameter of the gamma distribution to an inverse scale parameter is the set threshold.

9.-10. (canceled)

11. A non-transitory computer-readable storage medium, having a program stored thereon, wherein the program, when run by a processor, implements the steps in the method for standardizing the decommissioning definition of the power batteries according to claim 1.

12. A non-transitory computer-readable storage medium, having a program stored thereon, wherein the program, when run by a processor, implements the steps in the method for standardizing the decommissioning definition of the power batteries according to claim 2.

13. A non-transitory computer-readable storage medium, having a program stored thereon, wherein the program, when run by a processor, implements the steps in the method for standardizing the decommissioning definition of the power batteries according to claim 3.

14. A non-transitory computer-readable storage medium, having a program stored thereon, wherein the program, when run by a processor, implements the steps in the method for standardizing the decommissioning definition of the power batteries according to claim 4.

15. An electronic device, comprising a memory, a processor, and a program stored on the memory and runnable on the processor, wherein the processor, when running the program, implements the steps in the method for standardizing the decommissioning definition of the power batteries according to claim 1.

16. An electronic device, comprising a memory, a processor, and a program stored on the memory and runnable on the processor, wherein the processor, when running the program, implements the steps in the method for standardizing the decommissioning definition of the power batteries according to claim 2.

17. An electronic device, comprising a memory, a processor, and a program stored on the memory and runnable on the processor, wherein the processor, when running the program, implements the steps in the method for standardizing the decommissioning definition of the power batteries according to claim 3.

18. An electronic device, comprising a memory, a processor, and a program stored on the memory and runnable on the processor, wherein the processor, when running the program, implements the steps in the method for standardizing the decommissioning definition of the power batteries according to claim 4.
